(19) United States
(12) Patent Application Publication
(10) Pub. No.: US 2025/0218702 A1
(43) Pub. Date: Jul. 3, 2025

(54) IMPROVED DATA INTERFACE FOR A CIRCUIT BREAKER AND SYSTEM WITH SUCH A CIRUIT BREAKER

(71) Applicant: EATON INTELLIGENT POWER LIMITED, Dublin 4 (IE)

(72) Inventor: Tomas DRÁBEK, Praha (CZ)

(21) Appl. No.: 18/848,027

(22) PCT Filed: Mar. 24, 2023
(86) PCT No.: PCT/EP2023/025133

§ 371 Date: Sep. 17, 2024

(30) Foreign Application Priority Data
Mar. 24, 2022 (GB) 2204173.5

(51) Int. Cl. H01H 9/54; H01H 9/02

(52) U.S. Cl. CPC H01H 9/54; H01H 9/02

(57) ABSTRACT

Some embodiments relate to a circuit breaker, which includes a housing, a switching contact, a trigger unit acting on the switching contact, a circuit breaker microcontroller and a circuit breaker memory and an optical circuit breaker data interface, which is connected to a data input and/or output of the circuit breaker microcontroller and/or to a data input and/or output of the circuit breaker memory. Moreover, a system with such a circuit breaker is disclosed, which additionally includes an interface unit and/or a computer being connected to the circuit breaker.

### CROSS-REFERENCE TO RELATED APPLICATIONS

This application is a national phase filing under 35 C.F.R. § 371 of and claims priority to PCT Patent Application No. PCT/EP2023/025133, filed on Mar. 24, 2023, which claims the priority benefit under 35 U.S.C. § 119 of British Patent Application No. 2204173.5, filed on Mar. 24, 2022, the contents of which are hereby incorporated in their entireties by reference.

### TECHNICAL FIELD

The presently disclosed subject matter relates to a circuit breaker, which comprises a circuit breaker housing, a switching contact within the circuit breaker housing and metallic main power terminals, which are conductively connected to the switching contact and which protrude through the circuit breaker housing. Further on, the circuit breaker comprises a trigger unit acting on the switching contact, a circuit breaker microcontroller and a circuit breaker memory within the circuit breaker housing as well as a circuit breaker data interface, which is connected to a data input and/or output of the circuit breaker microcontroller and/or to a data input and/or output of the circuit breaker memory.

Moreover, the presently disclosed subject matter relates to a system, which comprises a circuit breaker of the above kind and
an interface unit designed to communicate with the circuit breaker microcontroller and/or the circuit breaker memory of the circuit breaker via the circuit breaker data interface or
a computer designed to communicate with the circuit breaker microcontroller and/or the circuit breaker memory of the circuit breaker via the circuit breaker data interface or
a computer with an interface unit designed to communicate with the circuit breaker microcontroller and/or the circuit breaker memory of the circuit breaker via the circuit breaker data interface.

### BACKGROUND ART

Such a circuit breaker and such a system are generally known in prior art. The switching contact is provided to switch off a current path between the main power terminals. For example, the switching contact can disconnect the main power terminals or switch off the current path respectively by means of the trigger unit in case of overcurrent or upon manual actuation. Moreover, data and commands may be exchanged between the circuit breaker and an interface unit or a computer via the circuit breaker data interface. For example, measurement values for a current flowing over the switching contact or a voltage of the current path can be sent from the circuit breaker to the interface unit or the computer. Furthermore, tripping characteristics for setup of the tripping unit may be sent from the interface unit or the computer to the circuit breaker.

A drawback of known solutions is that they do not sufficiently address the danger originating from the voltage, under which the switching contact and the current path is and which may rise up to the kilovolt range and even higher. Under bad circumstances, the electric energy coming from a power grid connected main power terminals may destroy the interface unit or the computer connected to the circuit breaker and hence is also a risk for personnel working with such an equipment.

### SUMMARY OF THE DISCLOSURE

Accordingly, an object of the presently disclosed subject matter is the provision of an improved circuit breaker and an improved system with such a circuit breaker. In particular, a solution shall be provided, which overcomes the drawbacks mentioned hereinbefore and is safe if the circuit breaker is used in low voltage grids and even in case that the circuit breaker is used in medium and high voltage grids.

The object of the presently disclosed subject matter is solved by a circuit breaker as disclosed in the opening paragraph, wherein the circuit breaker data interface is an optical interface.

Moreover, the object of the presently disclosed subject matter is solved by a system as disclosed in the opening paragraph, comprising a circuit breaker of the above kind.

By means of the inventive measures, a computer or interface unit connected to the circuit breaker is galvanically separated from parts of the circuit breaker under high voltage and is even save against dangerous creeping voltage. Hence, neither the equipment connected to the circuit breaker, nor the personnel operating said equipment is exposed to the risk or danger of an electric shock originating from the power grid connected to the main power terminals of the circuit breaker.

In particular, data sent from the circuit breaker to the interface unit or the computer can be coded in the circuit breaker microcontroller and is converted into modulated light pulses in the circuit breaker data interface. Similarly, data received from the interface unit or the computer is converted in electric signals in the circuit breaker data interface and can be decoded in the circuit breaker microcontroller.

Further advantageous embodiments are disclosed in the claims and in the description as well as in the figures.

Beneficially, the optical circuit breaker data interface comprises
an optical circuit breaker output sender, which is connected to a data output or a combined data input/output of the circuit breaker microcontroller and/or the circuit breaker memory and which is arranged within the circuit breaker housing, and a circuit breaker output light guide, which is optically coupled to the optical circuit breaker output sender and which protrudes through the circuit breaker housing or is part of the same and/or
an optical circuit breaker input receiver, which is connected to a data input or a combined data input/output of the circuit breaker microcontroller and/or the circuit breaker memory and which is arranged within the circuit breaker housing, and a circuit breaker input light guide, which is optically coupled to the optical circuit breaker input receiver and which protrudes through the circuit breaker housing or is part of the same.

In this way, modulated light pulses representing the data to be transmitted can be guided from the optical circuit breaker output sender out of the circuit breaker housing or can be guided to the optical circuit breaker input receiver into the circuit breaker housing. By use of the proposed measures, a very good electrical insulation and safety against electrical shocks originating from the power grid connected to the main power terminals of the circuit breaker is obtained. In this embodiment, the modulated light pulses representing the data to be transmitted are received and/or sent by the interface unit or the computer. For this reason, an optical interface unit output receiver may optically be coupled to the optical circuit breaker output sender and/or an optical interface unit input sender may optically be coupled to the optical circuit breaker input receiver.

Accordingly it is beneficial if the interface unit comprises an optical interface unit data interface, metallic interface unit data terminals, an interface unit microcontroller and an interface unit memory, wherein the metallic interface unit data terminals are connected to the interface unit microcontroller and wherein the optical interface unit data interface comprises
an optical interface unit input sender, which is connected to a data output or a combined data input/output of the interface unit microcontroller and/or the interface unit memory and which is designed to be optically coupled to the optical circuit breaker input receiver of the circuit breaker and/or
an optical interface unit output receiver, which is connected to a data input or a combined data input/output of the interface unit microcontroller and/or the interface unit memory and which is designed to be optically coupled to the optical circuit breaker output sender of the circuit breaker.

In this way, modulated light pulses representing transmitted data can be received in the optical interface unit output receiver and can be converted there into electric signals. The electric signals are then decoded in the interface unit microcontroller, and decoded data can be provided to a computer connected to the interface unit via the metallic interface unit data terminals. Similarly, data can be sent from the computer to the interface unit via the metallic interface unit data terminals, can be coded in the interface unit microcontroller and can be converted into modulated light pulses in the optical interface unit input sender.

It should be noted at this point that the terms “input” and “output” consistently relate to the circuit breaker's view (strictly speaking to the view of it's circuit breaker microcontroller and/or the circuit breaker memory). That means, that data input to the circuit breaker is output from the optical interface unit input sender, and that data output from the circuit breaker is input to the optical interface unit output receiver. In other words, the terms “input” and “output” have a diametric meaning for the interface unit and the computer.

In another beneficial embodiment,
a) the optical circuit breaker data interface comprises an optical circuit breaker output sender, which is connected to a data output or a combined data input/output of the circuit breaker microcontroller and/or the circuit breaker memory, and an optical circuit breaker output receiver, which is optically coupled to the optical circuit breaker output sender, wherein both the optical circuit breaker output sender and the optical circuit breaker output receiver are arranged within the circuit breaker housing, and
   the circuit breaker comprises metallic circuit breaker data output terminals, which are connected to the optical circuit breaker output receiver and which protrude through the circuit breaker housing or
   the optical circuit breaker output receiver is connected to a data input or a combined data input/output of an interfacing microcontroller of the circuit breaker, and the circuit breaker comprises metallic circuit breaker data output terminals or combined circuit breaker data input/output terminals, which are connected to a data output or the combined data input/output of the interfacing microcontroller and which protrude through the circuit breaker housing and/or
b) the optical circuit breaker data interface comprises an optical circuit breaker input receiver, which is connected to a data input or a combined data input/output of the circuit breaker microcontroller and/or the circuit breaker memory, and an optical circuit breaker input sender, which is optically coupled to the optical circuit breaker input receiver, wherein both the optical circuit breaker input sender and the optical circuit breaker input receiver are arranged within the circuit breaker housing, and
   the circuit breaker comprises metallic circuit breaker data input terminals, which are connected to the optical circuit breaker input sender and which protrude through the circuit breaker housing or
   the optical circuit breaker input sender is connected to a data output or a combined data input/output of an interfacing microcontroller of the circuit breaker, and the circuit breaker comprises metallic circuit breaker data input terminals or combined circuit breaker data input/output terminals, which are connected to a data input or the combined data input/output of the interfacing microcontroller and which protrude through the circuit breaker housing.

In a first embodiment, metallic circuit breaker data output terminals of the circuit breaker are connected to the optical circuit breaker output receiver, and metallic circuit breaker data input terminals are connected to the optical circuit breaker input sender. Accordingly, coding of data sent to the circuit breaker and decoding of data received from the circuit breaker takes place in the interface unit or the computer. In a second embodiment, the circuit breaker comprises an interfacing microcontroller, which can take over coding and decoding of data to be exchanged between the circuit breaker and the interface unit or the computer. Hence, data transmission between the circuit breaker and the interface unit or the computer can be eased.

Beneficially, the circuit breaker comprises a battery within the circuit breaker housing, which is connected to power pins of the circuit breaker microcontroller and/or the circuit breaker memory. In this way, the circuit breaker microcontroller and/or the circuit breaker memory can internally be powered without the necessity of transferring power to the circuit breaker microcontroller and/or the circuit breaker memory from outside of the circuit breaker. Accordingly, a very good electrical insulation and safety against electrical shocks originating from the power grid connected to the main power terminals of the circuit breaker can be provided.

Alternatively, the circuit breaker can comprise a circuit breaker power interface, which is coupled to the power pins of the circuit breaker microcontroller and/or the circuit breaker memory. In this way, the circuit breaker microcontroller and/or the circuit breaker memory can be powered from outside of the circuit breaker. Accordingly, no measures have to be taken that a battery for powering the circuit breaker microcontroller and/or the circuit breaker memory has a certain power level.

Beneficially, the circuit breaker power interface can be a contactless interface. In this way, a galvanic separation can be provided between a power source for powering the circuit breaker microcontroller and/or the circuit breaker memory and the circuit breaker microcontroller and/or the circuit breaker memory as such. Accordingly, a very good electrical insulation and safety against electrical shocks originating from the power grid connected to the main power terminals of the circuit breaker can be provided.

Advantageously, the circuit breaker power interface can comprise an electromagnetic receiver arranged within the circuit breaker housing. In this way, power can electromagnetically be transmitted to the circuit breaker microcontroller and/or the circuit breaker memory. No power terminals are necessary on or in the circuit breaker for powering the circuit breaker microcontroller and/or the circuit breaker memory. Accordingly, a very good electrical insulation and safety against electrical shocks originating from the power grid connected to the main power terminals of the circuit breaker can be provided.

In another beneficial embodiment,
the circuit breaker power interface comprises an electromagnetic receiver and an electromagnetic circuit breaker sender electromagnetically coupled to each other, wherein both are arranged within the circuit breaker housing, and
the circuit breaker comprises metallic circuit breaker auxiliary power terminals, which are provided to feed power to the electromagnetic circuit breaker sender and which protrude through the circuit breaker housing.

In this embodiment, both the electromagnetic circuit breaker sender and the electromagnetic receiver are part of the circuit breaker. Galvanic separation is done by the circuit breaker power interface, which is fully integrated in the circuit breaker. Hence, the interface unit, the computer or a power unit for the circuit breaker does not need to have a contactless power interface but can be electrically connected to the circuit breaker.

In another advantageous embodiment, the circuit breaker comprises a circuit breaker power stage with circuit breaker switching transistors, which is
connected to the circuit breaker power interface (in particular to it's electromagnetic circuit breaker sender),
controlled by an interfacing microcontroller of the circuit breaker and
powered via the metallic circuit breaker auxiliary power terminals.

By these measures, the interface unit, the computer or a power unit for the circuit breaker does not need to provide an AC voltage to the circuit breaker. Instead, provision of a DC voltage is sufficient. This DC voltage is provided to the circuit breaker switching transistors and converted there into an AC voltage. For example, the circuit breaker switching transistors can form half bridges, which are connected to an electromagnetic circuit breaker sender of the circuit breaker. Control of the circuit breaker switching transistors or half bridges is done by the interfacing microcontroller.

Similar considerations can be made for the interface unit, which may comprise
i) metallic auxiliary interface unit power terminals,
ii) an interface unit power interface with an electromagnetic interface unit sender, which is designed to be electromagnetically coupled to the electromagnetic receiver of the circuit breaker and
iii) an interface unit power stage with interface unit switching transistors, which is
   connected to the interface unit power interface (in particular to it's electromagnetic interface unit sender),
   controlled by an interface unit microcontroller of the interface unit and
   powered via the metallic auxiliary interface unit power terminals.

In this embodiment, the conversion from a DC voltage to an AC voltage is done in a dedicated interface unit. Accordingly, the computer does not need to provide an AC voltage to the circuit breaker. Instead, provision of a DC voltage to the interface unit is sufficient. This DC voltage is provided to the interface unit switching transistors and converted there into an AC voltage. For example, the interface unit switching transistors can form half bridges, which are connected to an electromagnetic interface unit sender of the interface unit. Control of the interface unit switching transistors or half bridges is done by the interface unit microcontroller.

Beneficially the metallic circuit breaker data terminals and/or the metallic auxiliary power terminals are part of an USB socket. In this way, the interface unit or the computer can be connected to the circuit breaker by commonly used means. The same counts for the metallic interface unit data terminals and/or the metallic auxiliary interface unit power terminals of the interface unit which may be part of an USB socket as well.

Beneficially, the circuit breaker microcontroller is functionally coupled to the trigger unit and is designed
to receive tripping characteristics or a choice of tripping characteristics for the tripping unit through the circuit breaker data interface (for example in form of tripping curves B, C, D) and/or
to receive a command for running a self test and to send results of said self test through the circuit breaker data interface.

In this way, data can be sent to the circuit breaker to set up the tripping unit. For example, data representing tripping characteristics in form of tripping curves B, C, D can be sent to the circuit breaker. If a plurality of tripping characteristics is stored in the circuit breaker microcontroller or the tripping unit, it is sufficient to send a choice to set up the tripping unit. In an alternative embodiment, a self test can be run in the circuit breaker, for example testing internal functions of the circuit breaker. After the test, the results of the same can be sent back to the interface unit or computer.

In yet another beneficial embodiment, the circuit breaker comprises
a current sensor, which is connected to the circuit breaker microcontroller, wherein the circuit breaker microcontroller is designed to send a measurement value measured by the current sensor or a parameter derived from said measurement value (e.g. a harmonic distortion of a course of the current) via the circuit breaker data interface and/or
a voltage sensor, which is connected to the circuit breaker microcontroller, wherein the circuit breaker microcontroller is designed to send a measurement value measured by the voltage sensor or a parameter derived from said measurement value (e.g. a harmonic distortion of a course of the voltage) via the circuit breaker data interface.

In this embodiment, actual and also historic data related to a current flowing over the switching contact or the main power terminals and/or a voltage at the switching contact or at the main power terminals can be measured and can be read out by the interface unit or the computer. In addition, parameters derived from said current and/or voltage can be calculated in the circuit breaker microcontroller and can be sent to the interface unit or the computer, for example, a harmonic distortion of said current and/or voltage. The circuit breaker microcontroller may also be designed to calculate an electric power, an electric energy and/or a phase shift between voltage and current based on the measured values and to send the calculated value via the circuit breaker data interface.

It should be noted that the term “transmitter” may synonymously be used for the “sender” throughout this application. Accordingly, an “optical sender” may also be denoted as an “optical transmitter”, and an “electromagnetic sender” may also be denoted as an “electromagnetic transmitter”. The same counts for the verb “send”, for which the term “transmit” may be used instead. This applies to both “data transmission” and “power transmission”.

### BRIEF DESCRIPTION OF DRAWINGS

The presently disclosed subject matter now is described in more detail hereinafter with reference to particular embodiments, which the presently disclosed subject matter however is not limited to.

FIG. 1 shows a schematic of a first example of a system with a circuit breaker, an optically coupled interface unit and a computer;

FIG. 2 shows a schematic of a second example of a system with a circuit breaker with an optocoupler and a computer connected thereto;

FIG. 3 shows a system, which is similar to that of FIG. 1 but which comprises an additional contactless power interface between the circuit breaker and the interface unit;

FIG. 4 shows a system with a circuit breaker with an optocoupler and a contactless power transmitter and

FIG. 5 shows a system similar to that of FIG. 2 but which comprises an external power unit connected to the circuit breaker.

### DETAILED DESCRIPTION

Generally, same parts or similar parts are denoted with the same/similar names and reference signs. The features disclosed in the description apply to parts with the same/similar names respectively reference signs. Indicating the orientation and relative position is related to the associated figure, and indication of the orientation and/or relative position has to be amended in different figures accordingly as the case may be.

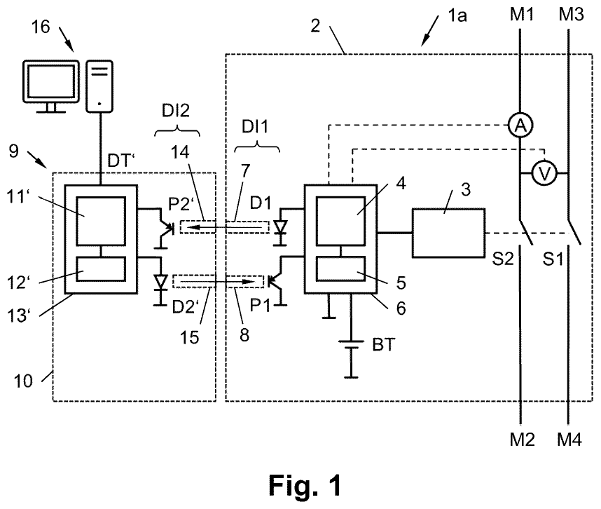

FIG. 1 shows a circuit breaker 1a, which comprises a circuit breaker housing 2, switching contacts S1, S2 within the circuit breaker housing 2, metallic main power terminals M1 . . . M4, which are conductively connected to the switching contacts S1, S2 and which protrude through the circuit breaker housing 2, and a trigger unit 3 acting on the switching contacts S1, S2. Moreover, the circuit breaker 1a comprises a circuit breaker microcontroller 4 and a circuit breaker memory 5, which form a circuit breaker control unit 6 and which are arranged within the circuit breaker housing 2. In this example, the circuit breaker 1a comprises a battery BT within the circuit breaker housing 2, which is connected to power pins of the circuit breaker microcontroller 4 and the circuit breaker memory 5. In addition, the circuit breaker 1a comprises an optional current sensor A and an optional voltage sensor V, which are connected to the circuit breaker microcontroller 4.

Further on, the circuit breaker 1a comprises an optical circuit breaker data interface DI1, which is connected both to a data input and to a data output of the circuit breaker microcontroller 4 and/or which is connected both to a data input and to a data output of the circuit breaker memory 5 respectively. In this example, the optical circuit breaker data interface DI1 comprises an optical circuit breaker output sender D1, which is connected to a data output or a combined data input/output of the circuit breaker microcontroller 4 and/or the circuit breaker memory 5 and which is arranged within the circuit breaker housing 2. In addition, the optical circuit breaker data interface DI1 in this example comprises an optional circuit breaker output light guide 7, which is optically coupled to the optical circuit breaker output sender D1 and which protrudes through the circuit breaker housing 2 or is part of the same. Moreover, the optical circuit breaker data interface DI1 comprises an optical circuit breaker input receiver P1, which is connected to a data input or a combined data input/output of the circuit breaker microcontroller 4 and/or the circuit breaker memory 5 and which is arranged within the circuit breaker housing 2. In addition, the optical circuit breaker data interface DI1 comprises an optional circuit breaker input light guide 8, which is optically coupled to the optical circuit breaker input receiver P1 and which protrudes through the circuit breaker housing 2 or is part of the same, too.

Furthermore, FIG. 1 shows an interface unit 9, which comprises an interface unit housing 10, an optical interface unit data interface DI2 within the interface unit housing 10, metallic interface unit data terminals DT′, an interface unit microcontroller 11′ and an interface unit memory 12′, which form an interface unit control unit 13′ and which are arranged within the interface unit housing 10. The metallic interface unit data terminals DT′ protrude through the interface unit housing 10 and are connected to the interface unit microcontroller 11′.

The optical interface unit data interface DI2 comprises an optical interface unit output receiver P2′, which is connected to a data input or a combined data input/output of the interface unit microcontroller 11′ and/or the interface unit memory 12′ and which is designed to be optically coupled to the optical circuit breaker output sender D1 of the circuit breaker 1a. For this reason, the optical interface unit data interface DI2 comprises an optional interface unit output light guide 14, which is optically coupled to the optical interface unit output receiver P2′ and which protrudes through the interface unit housing 10 or is part of the same.

Moreover, the optical interface unit data interface DI2 comprises an optical interface unit input sender D2′, which is connected to a data output or a combined data input/output of the interface unit microcontroller 11′ and/or the interface unit memory 12′ and which is designed to be optically coupled to the optical circuit breaker input receiver P1 of the circuit breaker 1a. For this reason, the optical interface unit data interface DI2 comprises an optional interface unit input light guide 15, which is optically coupled to the optical interface unit input sender D2′ and which protrudes through the interface unit housing 10 or is part of the same as well.

Finally, FIG. 1 shows a computer 16, which is connected to the interface unit 9 via its metallic interface unit data terminals DT′. Overall, FIG. 1 shows a system, comprising the circuit breaker 1a, the interface unit 9 and the computer 16.

Again, it is noted that the terms “input” and “output” consitently relate to the circuit breaker's view (strictly speaking to the view of it's circuit breaker microcontroller 4 and/or the circuit breaker memory 5) and that the terms “input” and “output” have a diametric meaning for the interface unit 9 and the computer 16.

The function of the system shown in FIG. 1 now is as follows:

The switching contacts S1, S2 are provided to disconnect the first main power terminal M1 from the second main power terminal M2 and to disconnect the third main power terminal M3 from the fourth main power terminal M4. In other words, the switching contacts S1, S2 are provided to switch off a first current path between the first main power terminal M1 and the second main power terminal M2 and to switch off a second current path between the third main power terminal M3 and the fourth main power terminal M4. In this example, the switching contacts S1, S2 are separated from each other by means of the trigger unit 3, for example, in case of overcurrent or upon manual actuation. It should be noted that although in FIG. 1 a two-pole circuit breaker 1a with two switching contacts S1, S2 is shown, the technical teaching applies to any number of poles or switching contacts S1, S2 equivalently, for example, to one-pole circuit breakers, three-pole circuit breakers and four-pole circuit breakers. The switching function of a circuit breaker 1a in principle is known per se and thus it is not explained in more detail at this point.

In addition, a current through the first current path between the first main power terminal M1 and the second main power terminal M2 is measured by the optional current sensor A, and a voltage is measured between the first main power terminal M1 and the third main power terminal M3 by the optional voltage sensor V. The circuit breaker microcontroller 4, which the current sensor A is connected to, can be designed to send a measurement value measured by the current sensor A or a parameter derived from said measurement value via the circuit breaker data interface DI1. A parameter derived from said measurement value for example can be a harmonic distortion of said current. Moreover, the circuit breaker microcontroller 4, which the voltage sensor V is connected to, can be designed to send a measurement value measured by the voltage sensor V or a parameter derived from said measurement value via the circuit breaker data interface DI1 as well. A parameter derived from said measurement value for example can be a harmonic distortion of said voltage. In particular, the circuit breaker microcontroller 4 may be provided to code the measurement value or parameters before they are sent via the circuit breaker data interface DI1. Further parameters, which can be calculated by the circuit breaker microcontroller 4 are an electric power, an electric energy and/or a phase shift between voltage and current based on the measured values.

In detail, said measurement values or parameters are transmitted to the interface unit 9 by means of the optical circuit breaker output sender D1. Here, the optical circuit breaker output sender D1 is directly connected to the circuit breaker control unit 6. However, a driver stage may be arranged between the circuit breaker control unit 6 and the optical circuit breaker output sender D1 as the case may be.

Modulated light pulses generated by the optical circuit breaker output sender D1 and representing the data to be transmitted pass the circuit breaker output light guide 7 and the interface unit output light guide 14 before they reach the optical interface unit output receiver P2′, where the modulated light pulses are converted back to electric signals again. These electric signals are received by the interface unit microcontroller 11′, decoded there and provided to the computer 16 at the interface unit data terminals DT′. For example, the interface unit data terminals DT′ may be part of an USB socket (“universal serial bus”). Accordingly, the measurement values or parameters measured by the current sensor A or the voltage sensor V may be provided to the computer 16 according to an USB standard.

In this example, the system in shown in FIG. 1 is not only designed to transmit measurement values or parameters derived therefrom from the circuit breaker 1a to the computer 16 via the interface unit 9, but also to transmit data from the computer 16 to the circuit breaker 1a via the interface unit 9.

For example, the circuit breaker microcontroller 4 can be functionally coupled to the trigger unit 3 and can be designed to receive tripping characteristics or a choice of tripping characteristics for the tripping unit 3 through the circuit breaker data interface DI1 and/or to receive a command for running a self test and to send results of said self test through the circuit breaker data interface DI1. For example, said tripping characteristics can be defined by tripping curves B, C and D providing a different (fast, medium, slow) time/current behavior of the circuit breaker 1a. A self test, for example, can be provided to test the proper function of the tripping unit 3.

If data or commands are to be transmitted to the circuit breaker 1a, said data or commands are sent from the computer 16 to the interface unit 9 via the interface unit data terminals DT′ (which again may be part of an USB socket) and are received in the interface unit microcontroller 11′. Here the data or commands are prepared to be sent via the circuit breaker data interface DI1. In detail, said data or commands are transmitted to the circuit breaker 1a by means of the optical interface unit input sender D2′, which converts electric signal into modulated light pulses. Here, the optical interface unit input sender D2′ is directly connected to the interface unit microcontroller 11′. However, a driver stage may be arranged between the interface unit microcontroller 11′ and the optical interface unit input sender D2′ as the case may be.

The modulated light pulses representing the data to be transmitted pass the interface unit input light guide 15 and the circuit breaker input light guide 8 before they reach the optical circuit breaker input receiver P1, where the modulated light pulses are converted back to electric signals again. These electric signals are received by the circuit breaker microcontroller 4, decoded there and used to change tripping characteristics of the trigger unit 3 or for starting a self test there for example.

Of course, the function of the circuit breaker microcontroller 4 and the interface unit microcontroller 11′ is not limited to the aforementioned functions, but the circuit breaker microcontroller 4 and the interface unit microcontroller 11′ may take over further functions as well. The circuit breaker memory 5 and the interface unit memory 12′ can be used for storing both data and executable code. In the example shown in FIG. 1, the circuit breaker microcontroller 4 and the circuit breaker memory 5 are integral part of the circuit breaker control unit 6. This is no necessary condition and the circuit breaker microcontroller 4 and the circuit breaker memory 5 can be provided as separate devices as well. The same counts for the interface unit control unit 13′, which the interface unit microcontroller 11′ and the interface unit memory 12′ are integral part of. Again, the interface unit microcontroller 11′ and the interface unit memory 12′ can be provided as separate devices as well.

It should also be noted that data can be directed to the circuit breaker microcontroller 4 and/or to the circuit breaker memory 5 or can be read from the circuit breaker microcontroller 4 and/or to the circuit breaker memory 5. Similarly, data can be directed to the interface unit microcontroller 11′ and/or to the interface unit memory 12′ or can be read from the interface unit microcontroller 11′ and/or to the interface unit memory 12′.

The optical circuit breaker output sender D1 and the optical interface unit input sender D2′ each are embodied as a light emitting diode. This is a beneficial solution, however, the use of other optional senders is possible as well. The same counts for the optical circuit breaker input receiver P1 and the optical interface unit output receiver P2′, which each are embodied as a phototransistor. Although this is a beneficial solution, the use of other optical receivers is possible as well.

The use of the circuit breaker output light guide 7, the circuit breaker input light guide 8, the interface unit output light guide 14 and the interface unit input light guide 15 is advantageous but not necessary because optical coupling of the optical circuit breaker data interface DI1 and the optical interface unit data interface DI2 can be done in another way as well.

Further on the optical circuit breaker data interface DI1 and the optical interface unit data interface DI2 do not necessarily support bidirectional data transmission. Instead, it is possible that data can only be sent form the circuit breaker 1a to the interface unit 9 or from the interface unit 9 to the circuit breaker 1a.

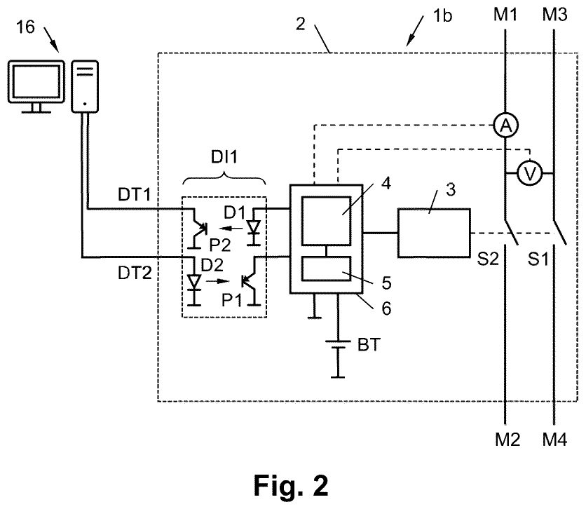

FIG. 2 shows a second embodiment of a system, which is similar to the system shown in FIG. 1. In contrast, the system of FIG. 2 does not comprise an interface unit 9. Instead, the computer 16 is directly connected to circuit breaker 1b of FIG. 2.

A further difference is that the circuit breaker data interface DI1 basically forms an optocoupler and comprises both an optical circuit breaker output sender D1 and an optical circuit breaker output receiver P2 optically coupled thereto as well as both an optical circuit breaker input sender D2 and an optical circuit breaker input receiver P1 optically coupled thereto. In detail, the optical circuit breaker output sender D1 is connected to a data output or a combined data input/output of the circuit breaker microcontroller 4 and/or the circuit breaker memory 5. Both the optical circuit breaker output sender D1 and the optical circuit breaker output receiver P2 are arranged within the circuit breaker housing 2, wherein the circuit breaker 1b comprises metallic circuit breaker data output terminals DT1, which are connected to the optical circuit breaker output receiver P2 and which protrude through the circuit breaker housing 2. Moreover, the optical circuit breaker input receiver P1 is connected to a data input or a combined data input/output of the circuit breaker microcontroller 4 and/or the circuit breaker memory 5. Both the optical circuit breaker input sender D2 and the optical circuit breaker input receiver P1 are arranged within the circuit breaker housing 2, wherein the circuit breaker 1b comprises metallic circuit breaker data input terminals DT2, which are connected to the optical circuit breaker input sender D2 and which protrude through the circuit breaker housing 2. The optical circuit breaker input sender D2 may be embodied as a light emitting diode and the optical circuit breaker output receiver P2 may be embodied as phototransistor. The metallic circuit breaker data terminals DT1, DT2 may be part of an USB socket.

The function of the system shown in FIG. 2 in parts equals the function of the system shown in FIG. 1, in detail in view of the switching contacts S1, S2, the main power terminals M1 . . . M4, the trigger unit 3, the optional current sensor A, the optional voltage sensor V, the circuit breaker microcontroller 4, the circuit breaker memory 5, the circuit breaker control unit 6, the optical circuit breaker output sender D1, the optical circuit breaker input receiver P1 and the data and commands exchanged between the circuit breaker 1b and the computer 16.

Modulated light pulses representing the data to be transmitted reach the optical circuit breaker output receiver P2, where the modulated light pulses are converted back to electric signals again. These electric signals are received in the computer 16 and are decoded there. Data or commands which are to be transmitted to the circuit breaker 1a are coded by the computer 16 and converted into modulated light pulses in the optical circuit breaker input sender D2. These modulated light pulses reach the optical circuit breaker input receiver P1, where the modulated light pulses are converted back to electric signals again. These electric signals are received by the circuit breaker microcontroller 4 and decoded there as already explained in view of the example shown in FIG. 1.

The optical circuit breaker data interface DI1 does not necessarily support bidirectional data transmission. Instead, it is possible that data can only be sent form the circuit breaker 1ba to the computer 16 or from the computer 16 to the circuit breaker 1b.

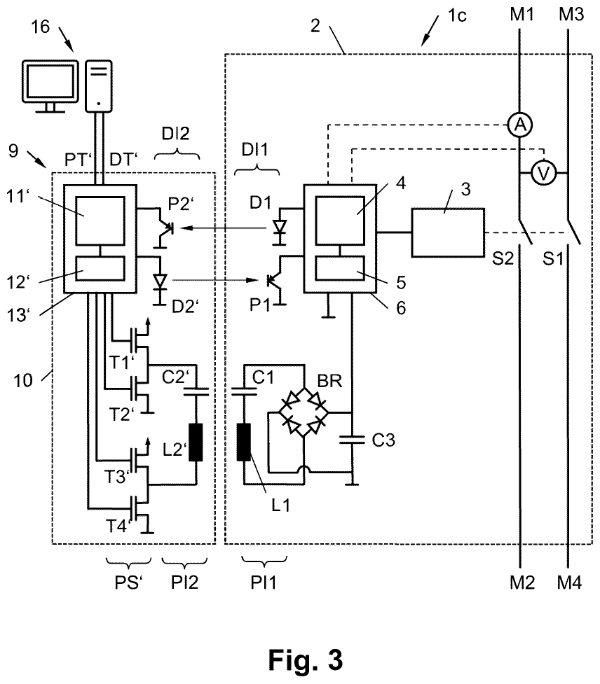

FIG. 3 shows a third embodiment of a system, which is similar to the system shown in FIG. 1. In contrast, the system of FIG. 3 does not comprise a battery BT but a circuit breaker power interface PI1, which is coupled to the power pins of the circuit breaker microcontroller 4 and/or the circuit breaker memory 5. In detail, the circuit breaker power interface PI1 is a contactless interface and comprises an electromagnetic receiver L1 arranged within the circuit breaker housing 2. Here the electromagnetic receiver L1 is embodied as a coil and is in series connection with a first circuit breaker capacitor C1. Downstream of this series connection there is a bridge rectifier BR, which powers the circuit breaker microcontroller 4 and the circuit breaker memory 5, wherein power fluctuations are damped by a third circuit breaker capacitor C3.

A further difference to the system shown in FIG. 1 is that the interface unit 9 comprises
i) metallic auxiliary interface unit power terminals PT′,
ii) an interface unit power interface PI2 with an electromagnetic interface unit sender L2′, which is designed to be electromagnetically coupled to the electromagnetic receiver L1 of the circuit breaker 1c and
iii) an interface unit power stage PS′ with interface unit switching transistors T1′ . . . T4′, which is connected to the interface unit power interface PI2 (in particular to the electromagnetic interface unit sender L2′), controlled by an interface unit microcontroller 11′ of the interface unit 9 and powered via the metallic auxiliary interface unit power terminals PT′.

In detail, the electromagnetic interface unit sender L2′ is embodied as a coil and is in series connection with an interface unit capacitor C2′. The interface unit switching transistors T1′ . . . T4′ form half bridges, wherein a first half bridge is formed by the first and second interface unit switching transistors T1′, T2′ and wherein a second half bridge is formed by the third and fourth interface unit switching transistors T3′, T4′.

The first half bridge is connected to a first end of the series connection of the electromagnetic interface unit sender L2′ and the interface unit capacitor C1, and the second half bridge is connected to a second end of said series connection. Power is supplied from the computer 16 to the transistors T1′ . . . T4′ via the metallic auxiliary interface unit power terminals PT′. In particular, the metallic auxiliary interface unit power terminals PT′ can be part of an USB socket.

The function of the system shown in FIG. 3 in parts equals the function of the system shown in FIG. 1, in detail in view of the switching contacts S1, S2, the main power terminals M1 . . . M4, the trigger unit 3, the optional current sensor A, the optional voltage sensor V, the circuit breaker microcontroller 4, the circuit breaker memory 5, the circuit breaker control unit 6, the optical circuit breaker output sender D1, the optical circuit breaker input receiver P1, the optical interface unit input sender D2′, the optical interface unit output receiver P2′, the interface unit microcontroller 11′, the interface unit memory 12′, the interface unit control unit 13′ and the data and commands exchanged between the circuit breaker 1c and the computer 16. The system of FIG. 3 does not comprise light guides 7, 8, 14, 15, but it may comprise them as the case may be.

However, the circuit breaker microcontroller 4 and the circuit breaker memory 5 are powered in a different way. In detail, the half bridges are controlled by the interface unit microcontroller 11′ in a way that DC power originating from the computer 16 is converted into AC power, which is contactlessly transmitted from the electromagnetic interface unit sender L2′ of the interface unit 9 to the electromagnetic receiver L1 of the circuit breaker 1c and converted back to DC power by the bridge rectifier BR before it is transmitted to the circuit breaker microcontroller 4 and the circuit breaker memory 5.

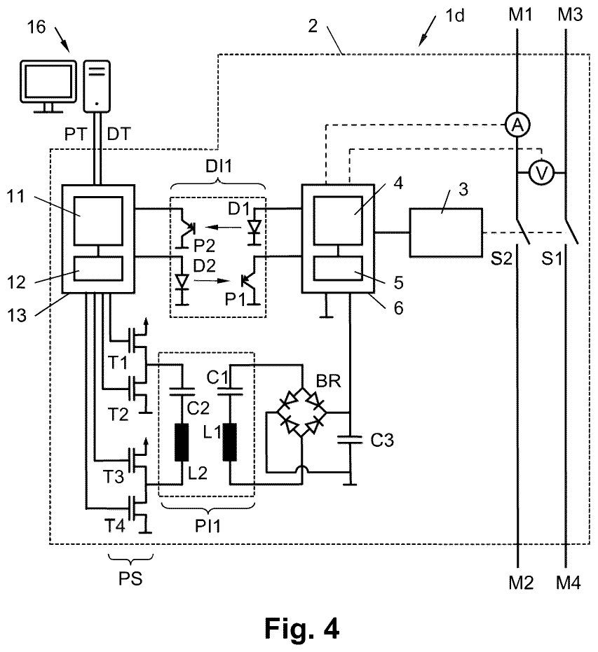

FIG. 4 shows a fourth embodiment of a system, which is similar to the system shown in FIG. 3. In contrast, the system of FIG. 4 does not comprise an interface unit 9. Instead, the computer 16 is directly connected to circuit breaker 1d of FIG. 4.

Like in the embodiment of FIG. 2 the circuit breaker data interface DI1 forms an optocoupler with an optical circuit breaker output sender D1, an optical circuit breaker output receiver P2, an optical circuit breaker input sender D2 and an optical circuit breaker input receiver P1. That is why the technical teaching related to the circuit breaker data interface DI1 shown in FIG. 2 similarly applies to the circuit breaker 1d of FIG. 4. The only difference is that the optical circuit breaker output receiver P2 and the optical circuit breaker input sender D2 are coupled to an interfacing microcontroller 11 and an interfacing memory 12, which form an interfacing control unit 13 and are part of the circuit breaker 1d. A similar structure is shown in the embodiment of FIG. 1 where the optical interface unit input sender D2′ and the optical interface unit output receiver P2′ are connected to the interface unit microcontroller 11′ and an interface unit memory 12′. In other words, the optical interface unit output receiver P2′ of FIG. 1 becomes the optical circuit breaker output receiver P2 of FIG. 4, the optical interface unit input sender D2′ becomes the optical circuit breaker input sender D2, the interface unit microcontroller 11′ becomes the interfacing microcontroller 11 and an interface unit memory 12′ becomes the interfacing memory 12. That is why the technical teaching related to the connection of the circuit breaker data interface DI1 to the interface unit control unit 13′ shown in FIG. 1 similarly applies to the circuit breaker 1d of FIG. 4.

Further on, the power transfer from the computer 16 to the circuit breaker microcontroller 4 and/or the circuit breaker memory 5 shown in FIG. 4 is similar to the power transfer from the computer 16 to the circuit breaker microcontroller 4 and/or the circuit breaker memory 5 shown in FIG. 3. The only difference is that the parts and functions of the circuit breaker power interface PI1 and the interface unit power interface PI2 of FIG. 3 are integrated into a single circuit breaker power interface PI1 in FIG. 4. In other words, the electromagnetic interface unit sender L2′ of FIG. 3 becomes the electromagnetic circuit breaker sender L2 of FIG. 4, the interface unit capacitor C2′ becomes the second circuit breaker capacitor C2, the interface unit transistors T1′ . . . T4′ become the circuit breaker transistors T1 . . . T4 and the interface unit power stage PS′ becomes the circuit breaker power stage PS. That is why the technical teaching to the power transfer related to FIG. 3 equally applies to the power transfer of FIG. 4. In this embodiment, the electromagnetic receiver L1 and the electromagnetic circuit breaker sender L2, which is electromagnetically coupled to the electromagnetic receiver L1, are both arranged within the circuit breaker housing 2.

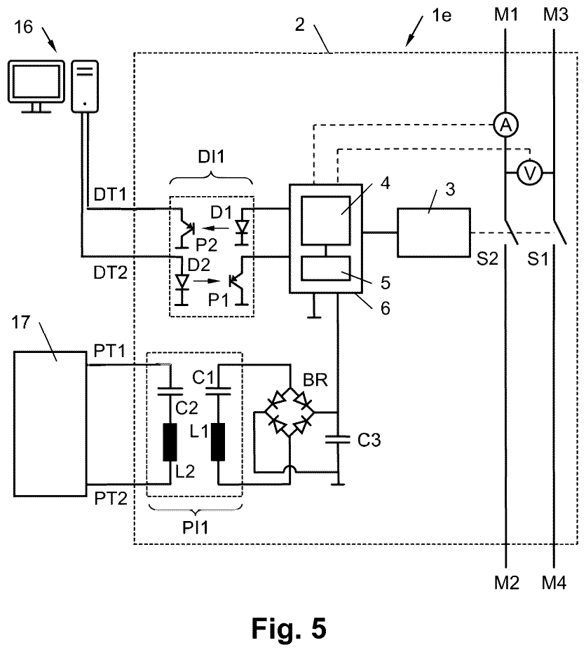

FIG. 5 finally shows a system which is similar to that of FIG. 2. The only difference is that the system of FIG. 5 does not comprise a battery BT but a separate external power unit 17, which is electrically connected to a circuit breaker power interface PI1, which is embodied like the circuit breaker power interface PI1 of FIG. 4. In contrast, the power unit 17 of this embodiment is considered to provide an AC power, which is contactelssly transmitted to the circuit breaker microcontroller 4 and the circuit breaker memory 5 by use of the circuit breaker power interface PI1. In detail, the power unit 17 is connected to the series connection of the electromagnetic circuit breaker sender L2 and the second circuit breaker capacitor C2 via the auxiliary circuit breaker power terminals PT1, PT2.

By means of the inventive measures, a computer 16 or interface unit 9 connected to the circuit breaker 1a . . . 1e is galvanically separated from parts of the circuit breaker 1a . . . 1e under high voltage and is even save against dangerous creeping voltage. Hence, neither the equipment connected to the circuit breaker 1a . . . 1e, nor the personnel operating said equipment is exposed to the risk or danger of an electric shock originating from the power grid connected to the main power terminals M1 . . . M4 of the circuit breaker 1a . . . 1e.

It is noted that the presently disclosed subject matter is not limited to the embodiments disclosed hereinbefore, but combinations of the different variants are possible. In reality, the system may have more or less parts than shown in the figures. Moreover, the description may comprise subject matter of further independent inventions.

It should also be noted that the term “comprising” does not exclude other elements and the use of articles “a” or “an” does not exclude a plurality. Also elements described in association with different embodiments may be combined. It should also be noted that reference signs in the claims should not be construed as limiting the scope of the claims.

### LIST OF REFERENCE NUMERALS

1a . . . 1e circuit breaker
2 circuit breaker housing
3 trigger unit
4 circuit breaker microcontroller
5 circuit breaker memory
6 circuit breaker control unit
7 circuit breaker output light guide
8 circuit breaker input light guide
9 interface unit
10 interface unit housing
11 interfacing microcontroller
12 interfacing memory
13 interfacing control unit
11′ interface unit microcontroller
12 interface unit memory
13′ interface unit control unit
14 interface unit output light guide
15 interface unit input light guide
16 computer
17 power unit
BT battery
BR bridge rectifier
C1 . . . C3 circuit breaker capacitor
C2′ interface unit capacitor
D1 light emitting diode/optical circuit breaker output sender
D2 light emitting diode/optical circuit breaker input sender
D2′ light emitting diode/optical interface unit input sender
   DI1 optical circuit breaker data interface
   DI2 optical interface unit data interface
   DT1 circuit breaker data output terminal
DT2 circuit breaker data input terminal
DT combined circuit breaker data input/output terminal
DT′ combined interface unit data input/output terminal
L1 secondary coil/electromagnetic receiver
L2 primary coil/electromagnetic circuit breaker sender
L2′ primary coil/electromagnetic interface unit sender
M1 . . . M4 main power terminals
P1 phototransistor/optical circuit breaker input receiver
P2 phototransistor/optical circuit breaker output receiver
P2′ phototransistor/optical interface unit output receiver
PI1 circuit breaker power interface
PI2 interface unit power interface
PS circuit breaker power stage
PS′ interface unit power stage
PT, PT1, PT2 auxiliary circuit breaker power terminal
PT′ auxiliary interface unit power terminal
S1, S2 switching contact
T1 . . . T4 circuit breaker transistor
T1′ . . . T4′ interface unit transistor

1. A Circuit breaker, comprising:
a circuit breaker housing;
a switching contact within the circuit breaker housing;
metallic main power terminals, which are conductively connected to the switching contact and which protrude through the circuit breaker housing;
a trigger unit acting on the switching contact;
a circuit breaker microcontroller and a circuit breaker memory within the circuit breaker housing; and
a circuit breaker data interface, which is connected to a data input and output of the circuit breaker microcontroller, and/or to a data input and output of the circuit breaker memory,
wherein
the circuit breaker data interface is an optical interface; and characterized by
a circuit breaker power interface (PI1), which is coupled to the power pins of the circuit breaker microcontroller (4) and/or the circuit breaker memory (5), and wherein the circuit breaker power interface (PI1) is a contactless interface.

2. The Circuit breaker as claimed in claim 1, wherein the optical circuit breaker data interface comprises
an optical circuit breaker output sender, which is connected to a data output or a combined data input/output of the circuit breaker microcontroller and/or the circuit breaker memory and which is arranged within the circuit breaker housing (2), and a circuit breaker output light guide, which is optically coupled to the optical circuit breaker output sender and which protrudes through the circuit breaker housing or is part of the same and/or
an optical circuit breaker input receiver, which is connected to a data input or a combined data input/output of the circuit breaker microcontroller and/or the circuit breaker memory and which is arranged within the circuit breaker housing, and a circuit breaker input light guide, which is optically coupled to the optical circuit breaker input receiver and which protrudes through the circuit breaker housing or is part of the same.

3. The Circuit breaker as claimed in claim 1, wherein
a) the optical circuit breaker data interface comprises an optical circuit breaker output sender, which is connected to a data output or a combined data input/output of the circuit breaker microcontroller and/or the circuit breaker memory, and an optical circuit breaker output receiver, which is optically coupled to the optical circuit breaker output sender, wherein both the optical circuit breaker output sender and the optical circuit breaker output receiver are arranged within the circuit breaker housing, and
the circuit breaker comprises metallic circuit breaker data output terminals, which are connected to the optical circuit breaker output receiver and which protrude through the circuit breaker housing or
the optical circuit breaker output receiver is connected to a data input or a combined data input/output of an interfacing microcontroller of the circuit breaker, and the circuit breaker comprises metallic circuit breaker data output terminals or combined circuit breaker data input/output terminals, which are connected to a data output or the combined data input/output of the interfacing microcontroller and which protrude through the circuit breaker housing and/or
b) the optical circuit breaker data interface comprises an optical circuit breaker input receiver, which is connected to a data input or a combined data input/output of the circuit breaker microcontroller and/or the circuit breaker memory, and an optical circuit breaker input sender, which is optically coupled to the optical circuit breaker input receiver, wherein both the optical circuit breaker input sender and the optical circuit breaker input receiver are arranged within the circuit breaker housing, and
the circuit breaker comprises metallic circuit breaker data input terminals, which are connected to the optical circuit breaker input sender and which protrude through the circuit breaker housing or
the optical circuit breaker input sender is connected to a data output or a combined data input/output of an interfacing microcontroller of the circuit breaker, and the circuit breaker comprises metallic circuit breaker data input terminals or combined circuit breaker data input/output terminals, which are connected to a data input or the combined data input/output of the interfacing microcontroller and which protrude through the circuit breaker housing.

4. The Circuit breaker as claimed in claim 1, characterized in a battery within the circuit breaker housing, which is connected to power pins of the circuit breaker microcontroller and/or the circuit breaker memory.

5. (canceled)

6. (canceled)

7. The Circuit breaker as claimed in claim 1, wherein the circuit breaker power interface comprises an electromagnetic receiver arranged within the circuit breaker housing.

8. The Circuit breaker as claimed in claim 4, wherein
the circuit breaker power interface comprises an electromagnetic receiver and an electromagnetic circuit breaker sender electromagnetically coupled to each other and both being arranged within the circuit breaker housing, and
the circuit breaker comprises metallic circuit breaker auxiliary power terminals, which are provided to feed power to the electromagnetic circuit breaker sender and which protrude through the circuit breaker housing.

9. The Circuit breaker as claimed in claim 8, characterized in a circuit breaker power stage with circuit breaker switching transistors, which is
connected to the circuit breaker power interface,
controlled by an interfacing microcontroller of the circuit breaker and
powered via the metallic circuit breaker auxiliary power terminals.

10. The Circuit breaker as claimed in claim 3, wherein the metallic circuit breaker data terminals and/or the metallic auxiliary power terminals are part of an USB socket.

11. The Circuit breaker as claimed in claim 1, wherein the circuit breaker microcontroller is functionally coupled to the trigger unit and is designed
to receive tripping characteristics or a choice of tripping characteristics for the tripping unit through the circuit breaker data interface and/or
to receive a command for running a self test and to send results of said self test through the circuit breaker data interface.

12. The Circuit breaker as claimed in claim 1, characterized in a
current sensor, which is connected to the circuit breaker microcontroller, wherein the circuit breaker microcontroller is designed to send a measurement value measured by the current sensor or a parameter derived from said measurement value via the circuit breaker data interface and/or
a voltage sensor, which is connected to the circuit breaker microcontroller, wherein the circuit breaker microcontroller is designed to send a measurement value measured by the voltage sensor or a parameter derived from said measurement value via the circuit breaker data interface.

13. The System, comprising a circuit breaker as claimed in claim 1, characterized in
an interface unit designed to communicate with the circuit breaker microcontroller and/or the circuit breaker memory of the circuit breaker via the circuit breaker data interface or
a computer designed to communicate with the circuit breaker microcontroller and/or the circuit breaker memory of the circuit breaker via the circuit breaker data interface or
a computer with an interface unit designed to communicate with the circuit breaker microcontroller and/or the circuit breaker memory of the circuit breaker via the circuit breaker data interface.

14. The System as claimed in claim 13, wherein the interface unit comprises, an optical interface unit data interface, metallic interface unit data terminals, an interface unit microcontroller and an interface unit memory, wherein the metallic interface unit data terminals are connected to the interface unit microcontroller and wherein the optical interface unit data interface comprises
an optical interface unit input sender, which is connected to a data output or a combined data input/output of the interface unit microcontroller and/or the interface unit memory and which is designed to be optically coupled to the optical circuit breaker input receiver of the circuit breaker and/or
an optical interface unit output receiver, which is connected to a data input or a combined data input/output of the interface unit microcontroller and/or the interface unit memory and which is designed to be optically coupled to the optical circuit breaker output sender of the circuit breaker.

15. The System as claimed in claim 13, wherein the interface unit comprises
i) metallic auxiliary interface unit power terminals,
ii) an interface unit power interface with an electromagnetic interface unit sender, which is designed to be electromagnetically coupled to the electromagnetic receiver of the circuit breaker and
iii) an interface unit power stage with interface unit switching transistors, which is
connected to the interface unit power interface,
controlled by an interface unit microcontroller of the interface unit and
powered via the metallic auxiliary interface unit power terminals.
